(19) United States
(12) Patent Application Publication
(10) Pub. No.: US 2025/0018884 A1
(43) Pub. Date: Jan. 16, 2025

(54) WIRE HARNESS

(71) Applicant: YAZAKI CORPORATION, Tokyo (JP)

(72) Inventors: Hiroki Suganuma, Makinohara-shi (JP); Mitsuhisa Sano, Makinohara-shi (JP); Shuji Kimura, Makinohara-shi (JP); Terumitsu Sugimoto, Makinohara-shi (JP)

(21) Appl. No.: 18/755,583

(22) Filed: Jun. 26, 2024

(30) Foreign Application Priority Data
Jul. 13, 2023 (JP) 2023-114951

(51) Int. Cl. B60R 16/02

(52) U.S. Cl. CPC B60R 16/0215

(57) ABSTRACT

A wire harness includes a trunk module having a flexible substrate having flexibility, and a branch wire module having an electric wire connected to the flexible substrate. The flexible substrate is disposed along a reinforcement provided in an instrument panel and extending in a vehicle width direction of a vehicle, and is assembled to the reinforcement.

### CROSS-REFERENCE TO RELATED APPLICATION(S)

The present application claims priority to and incorporates by reference the entire contents of Japanese Patent Application No. 2023-114951 filed in Japan on Jul. 13, 2023.

### BACKGROUND OF THE INVENTION

### 1. Field of the Invention

The present invention relates to a wire harness.

### 2. Description of the Related Art

As a technique related to a conventional wire harness, for example, as disclosed in Japanese Patent Application Laid-open No. 5-110246, a wire harness mounted on a vehicle using a flexible substrate having flexibility has been known.

Such a wire harness has room for improvement in terms of assembly to a vehicle. For example, since the flexible substrate has flexibility and is easily deformed, it is difficult to stably assemble the flexible substrate to a vehicle body or the like.

### SUMMARY OF THE INVENTION

Therefore, an object of the present invention is to provide a wire harness capable of improving assemblability.

A wire harness, according to one aspect of the present invention, includes a trunk module having a flexible substrate having flexibility; and a branch wire module having an electric wire connected to the flexible substrate, wherein the flexible substrate is disposed along a reinforcement provided in an instrument panel and extending in a vehicle width direction of a vehicle, and is assembled to the reinforcement.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a perspective view of a wire harness according to a first embodiment;

FIG. 2 is an exemplary schematic plan view of the wire harness according to the first embodiment;

FIG. 3 is a perspective view of a wire harness according to a second embodiment;

FIG. 4 is a perspective view of a wire harness according to a third embodiment;

FIG. 5 is a perspective view of a wire harness according to a fourth embodiment;

FIG. 6 is an exploded perspective view of the wire harness according to the fourth embodiment;

FIG. 7 is an illustrative view of a clamp in the wire harness according to the fourth embodiment;

FIG. 8 is a perspective view of a wire harness according to a fifth embodiment;

FIG. 9 is an exploded perspective view of the wire harness according to the fifth embodiment;

FIG. 10 is an illustrative view of a clamp in the wire harness according to the fifth embodiment;

FIG. 11 is a perspective view of a wire harness according to a sixth embodiment;

FIG. 12 is an illustrative view of a flexible substrate in the wire harness according to the sixth embodiment; and

FIG. 13 is an illustrative view of a protective plate in the wire harness according to the sixth embodiment.

### DETAILED DESCRIPTION OF THE PREFERRED EMBODIMENTS

Hereinafter, embodiments according to the present invention will be described in detail with reference to the drawings. Note that the present invention is not limited by the embodiments. In addition, components in the following embodiments include those that can be easily replaced by those skilled in the art or those that are substantially the same.

### EMBODIMENTS

The present embodiment relates to a wire harness. In the following description, among a first direction, a second direction, and a third direction intersecting one another, the first direction is referred to as an “extending direction X”, the second direction is referred to as a “width direction Y”, and the third direction is referred to as a “height direction Z”. Here, the extending direction X, the width direction Y, and the height direction Z are orthogonal to each other. The extending direction X corresponds to an extending direction and a longitudinal direction of a flexible substrate of a trunk module. The width direction Y corresponds to the width direction of the flexible substrate of the trunk module. The height direction Z corresponds to the thickness direction of the flexible substrate of the trunk module. The width direction Y and the height direction Z correspond to an intersecting direction intersecting the extending direction X. In addition, each direction used in the following description represents a direction in a state in which each part is assembled to each other unless otherwise specified. The term “orthogonal” as used herein includes substantially orthogonal.

A wire harness according to a first embodiment will be described.

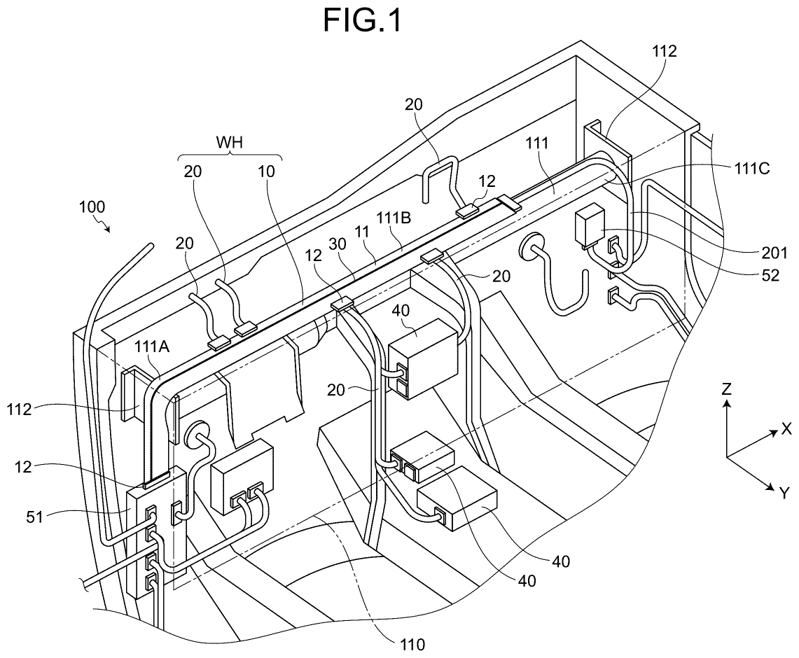

FIG. 1 is a perspective view of a wire harness WH according to a first embodiment, illustrating a state of being assembled to a vehicle 100. For example, a wire harness WH is installed and used inside an instrument panel 110 of the vehicle 100. The instrument panel 110 is an interior panel disposed in front of a vehicle interior along a vehicle width direction so as to face a driver seat and a passenger seat of the vehicle 100. In FIG. 1, the instrument panel 110 is indicated by a two-dot chain line. The wire harness WH connects devices mounted on the vehicle 100 and is used for power supply and signal communication. A reinforcement 111 is provided inside the instrument panel 110. The reinforcement 111 is a structural member or a reinforcing member installed inside the instrument panel 110, and is provided along a vehicle width direction (extending direction X). The reinforcement 111 is also referred to as a reinforce, or the like. The reinforcement 111 is formed of, for example, a metal hollow pipe, and flanges 112 are formed at both ends. One flange 112 is fixed to a left side of a body of the vehicle 100, and the other flange 112 is fixed to a right side of the body of the vehicle 100.

The wire harness WH includes a trunk module 10 and a plurality of branch wire modules 20. The trunk module 10 is a wiring module having a large number of transmission lines or wirings extending in the same direction, and is connected to, for example, a control unit or the like. The trunk module 10 includes a flexible substrate 11 and a plurality of trunk side connectors 12. The flexible substrate 11 is a planar circuit body in which a circuit is formed in a planar shape, is referred to as a flexible printed circuit (FPC), and is a flexible printed wiring board. The planar shape here also includes a substantially planar shape. The flexible substrate 11 is formed by, for example, bonding a base film, a conductor foil, and a coverlay with an adhesive layer interposed therebetween. The conductor foil is a wiring pattern of the flexible substrate 11 and configures a wiring portion of the flexible substrate 11. The flexible substrate 11 may be a single-sided substrate having a wiring pattern only on one side of the base film, or may be a double-sided substrate having wiring patterns on both sides of the base film. In the flexible substrate 11, electric components such as resistors and capacitors may or may not be mounted on the wiring pattern.

Here, the trunk module 10 is connected to an electronic control unit (ECU) 51 through any one of the plurality of trunk side connectors 12, and is connected to branch wire modules 20 through the other trunk side connectors 12. The ECU 51 here is a first control unit, and is typically a zone ECU that comprehensively controls devices in a peripheral region (zone) of the instrument panel 110, but is not limited thereto. The trunk side connector 12 is a connector attached to an end portion of the flexible substrate 11.

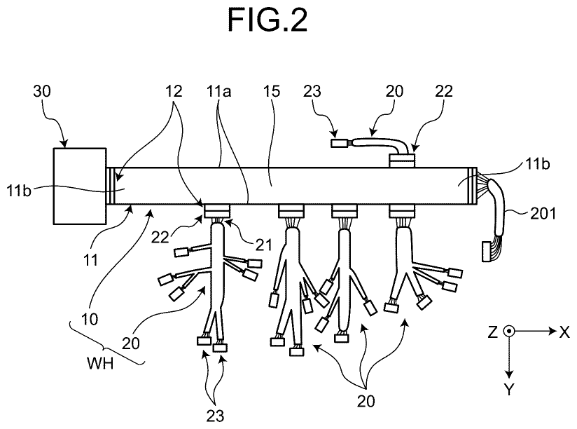

Each of the plurality of branch wire modules 20 is a wiring module having one end connected to the trunk side connector 12 of the trunk module 10 and the other end connected to various electronic devices 40 in the vehicle 100. Each of the branch wire modules 20 includes a plurality of conductive wiring members 21 (see FIG. 2), a branch wire side first connector 22 provided at one terminal of the plurality of wiring members 21 and mechanically and electrically connected to each of the trunk side connectors 12, and a branch wire side second connector 23 provided at the other terminal of the plurality of wiring members 21 and mechanically and electrically connected to various electronic devices 40 in the vehicle 100. The wiring member 21 is, for example, an electric wire having a conductor portion obtained by twisting a plurality of linear metal strands and an insulating covering portion covering the outside of the conductor portion. In addition, the wire harness WH may include a special electric wire 30. The special electric wire 30 is an electric wire that transmits a signal or power that is difficult to appropriately transmit on the flexible substrate 11, and is used, for example, for transmission of a signal of high-speed communication or large current power. The special electric wire 30 is routed along the reinforcement 111, for example.

FIG. 2 is a schematic plan view of the wire harness WH. The flexible substrate 11 is formed in a rectangular shape that is horizontally long in the vehicle width direction as a whole. That is, the flexible substrate 11 has a pair of first end portions 11a as long side portions and a pair of second end portions 11b as short side portions. The first end portions 11a are ends of the flexible substrate 11 on both sides in the vehicle front-rear direction (in FIG. 2, the width direction Y), and the second end portions 11b are ends of the flexible substrate 11 on both sides in the vehicle width direction (in FIG. 2, the extending direction X). In the present embodiment, at least one of the plurality of trunk side connectors 12 is installed at each of the first end portion 11a and the second end portion 11b of the flexible substrate 11.

Specifically, the trunk module 10 includes, for example, seven trunk side connectors 12. In this case, four trunk side connectors 12 are provided at one of the pair of first end portions 11a at intervals in the vehicle width direction, and one trunk side connector 12 is provided on the other. One trunk side connector 12 is provided on one of the pair of second end portions 11b, and one trunk side connector 12 is provided on the other. Six of these trunk side connectors 12 are connected to the branch wire modules 20 through the above-described branch wire side first connector 22, and the remaining one is connected to the ECU 51 through the ECU side connector. Specifications such as the number of poles of the trunk side connectors 12, arrangement of the trunk side connectors 12 in the flexible substrate 11, and the like can be appropriately changed according to the attachment position of the wire harness WH in the vehicle 100 and the like.

In FIG. 1, the flexible substrate 11 is disposed along the reinforcement 111 and assembled to the reinforcement. For example, the flexible substrate 11 may be directly assembled to the reinforcement 111 or may be attached through another member. For example, the flexible substrate 11 is attached to the reinforcement 111 with a back surface side facing a front surface of the reinforcement 111.

One end of the flexible substrate 11 extends to a position of one end portion 111A of the reinforcement 111, and the other end extends to between the central position 111B of the reinforcement 111 and the position of the other end portion 111C. For example, one end of the flexible substrate 11 extends to the position of the ECU 51 beyond the position of the one end portion 111A of the reinforcement 111. The other end of the flexible substrate 11 extends to a position beyond the central position 111B of the reinforcement 111, and is connected to the first electric wire module 201. The first electric wire module 201 is a part of the branch wire module 20 and has a wiring member 21 which is an electric wire. After being routed along the reinforcement 111, the first electric wire module 201 is deviated from the reinforcement 111 and connected to the ECU 52. The ECU 52 is a second control unit, and is typically a zone ECU that comprehensively controls devices in a peripheral region (zone) of the instrument panel 110, but is not limited thereto.

Next, assemblability of the wire harness WH according to the present embodiment will be described.

As illustrated in FIG. 1, in the wire harness WH according to the present embodiment, the flexible substrate 11 is used for the trunk module 10. The flexible substrate 11 is disposed and assembled along the reinforcement 111. Therefore, the wire harness WH according to the present embodiment can eliminate the three-dimensional routing of the flexible substrate 11, and the flexible substrate 11 can be easily assembled. That is, since the wire harness WH according to the present embodiment does not require three-dimensional routing of the flexible substrate 11, the flexible substrate 11 having low rigidity and strength can be easily assembled. Therefore, the wire harness WH according to the present embodiment can improve the assemblability.

In the wire harness WH according to the present embodiment, an installation space of the trunk module 10 can be reduced or thinned by assembling the flexible substrate 11 along the surface of the reinforcement 111. Therefore, an internal space of the vehicle can be effectively used.

In the wire harness WH according to the present embodiment, in the trunk module 10, the flexible substrate 11 is installed from one end portion 111A of the reinforcement 111 to a position between the central position 111B and the other end portion 111C. That is, the wire harness WH according to the present embodiment can be formed thin in the height direction at the driver's seat and the central position while suppressing the use amount of the flexible substrate 11, which is expensive, by partially using the flexible substrate 11 with respect to the reinforcement 111 in the trunk module 10. Therefore, the wire harness WH according to the present embodiment can reduce the size of the instrument panel 110. That is, in the wire harness WH according to the present embodiment, the installation space of the wire harness WH can be reduced or thinned in a section of the back of a handle and a center of the vehicle inside the instrument panel 110. Therefore, the wire harness WH according to the present embodiment can contribute to a need to suppress the height of the instrument panel 110.

As described above, in the wire harness WH of the present embodiment, the flexible substrate 11 is assembled to the reinforcement 111, so that three-dimensional routing of the flexible substrate can be eliminated, and the flexible substrate 11 can be easily assembled. Therefore, the wire harness WH according to the present embodiment can improve the assemblability.

In addition, in the wire harness WH of the present embodiment, the flexible substrate 11 is partially used with respect to the reinforcement 111 in the trunk module 10, so that it is possible to form the wire harness WH thin in the height direction at the driver's seat and the central position while suppressing the use amount of the flexible substrate 11 with high cost, and it is possible to miniaturize the instrument panel 110.

Next, a wire harness according to a second embodiment will be described.

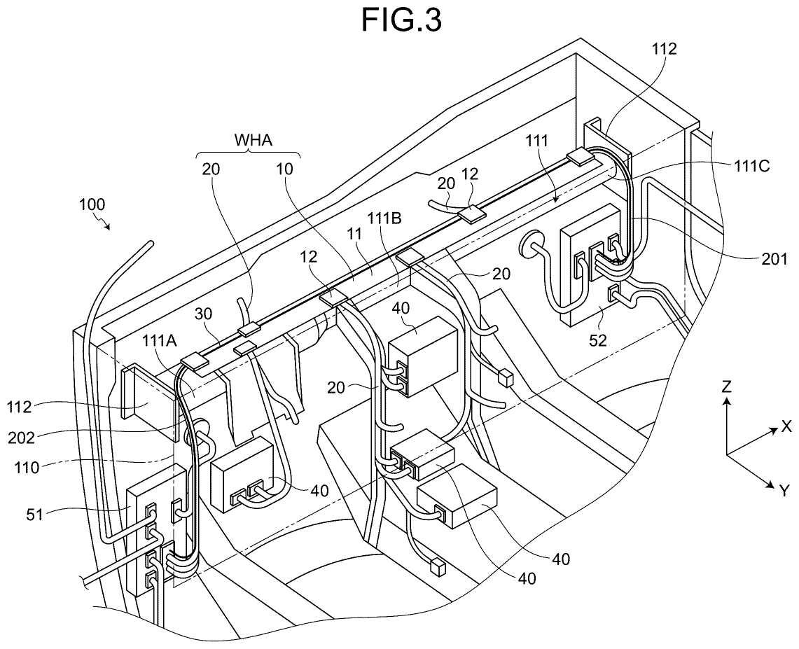

FIG. 3 is a perspective view of a wire harness WHA according to the second embodiment, illustrating a state of being assembled to a vehicle 100. The wire harness WHA according to the second embodiment is configured substantially similarly to the wire harness WH according to the first embodiment described above, and an installation range of the flexible substrate 11 with respect to the reinforcement 111 in the trunk module 10 is different. That is, in the wire harness WHA according to the second embodiment, the flexible substrate 11 is disposed from a position of one end portion 111A to a position of the other end portion 111C of the reinforcement 111. That is, the flexible substrate 11 is installed over the entire section of the reinforcement 111. Here, the entire section includes substantially the entire section.

A first electric wire module 201 is connected to the other end of the flexible substrate 11, and a second electric wire module 202 is connected to one end. The first electric wire module 201 and the second electric wire module 202 are wiring modules in which a wiring member 21 which is an electric wire is used as a transmission line. The first electric wire module 201 is connected to the flexible substrate 11 at the position of the end portion 111C of the reinforcement 111, is disposed away from the reinforcement 111, and is connected to, for example, the ECU 52. The second electric wire module 202 is connected to the flexible substrate 11 at the position of the end portion 111A of the reinforcement 111, is disposed away from the reinforcement 111, and is connected to, for example, the ECU 51.

The wire harness WHA according to the second embodiment is excellent in assemblability, and can be easily assembled to a vehicle. That is, in the wire harness WHA according to the second embodiment, the flexible substrate 11 is applied to a straight section of the reinforcement 111 in the trunk module 10, so that the wire harness WHA has high wiring performance and achieves good vehicle mounting.

As described above, the wire harness WHA according to the second embodiment can improve the assemblability by using the flexible substrate 11 in the section routed on the reinforcement 111 in the trunk module 10.

Next, a wire harness WHB according to a third embodiment will be described.

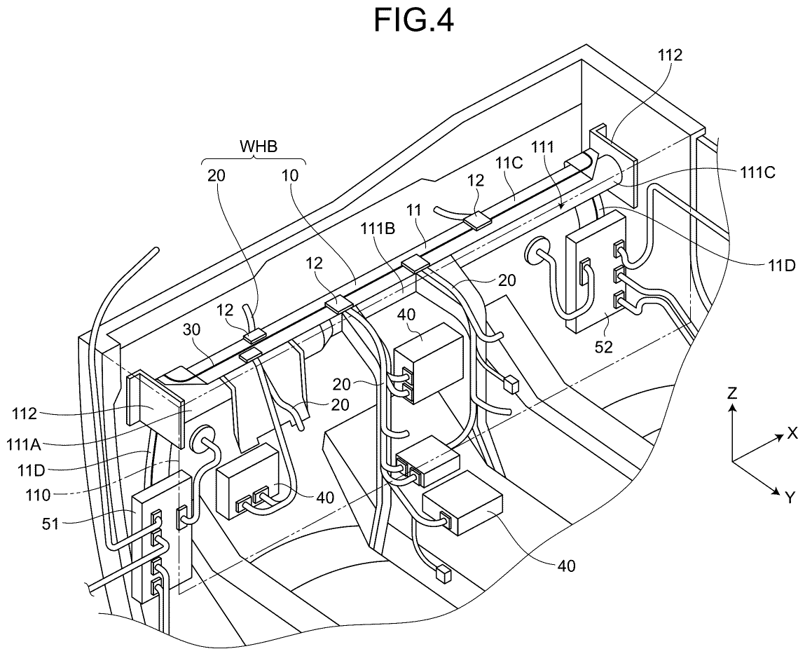

FIG. 4 is a perspective view of a wire harness WHB according to a third embodiment, and illustrates a state of being assembled to a vehicle 100. The wire harness WHB according to the third embodiment is configured substantially similarly to the wire harness WH according to the first embodiment described above, and an installation range of a flexible substrate 11 with respect to the reinforcement 111 in the trunk module 10 is different. That is, as illustrated in FIG. 4, in the wire harness WHA according to the third embodiment, the flexible substrate 11 is installed in the entire section of the trunk module 10. For example, in a case where the trunk module 10 is installed from an ECU 51 to an ECU 52, the flexible substrate 11 is installed over the entire section between the ECU 51 and the ECU 52.

The flexible substrate 11 has a straight portion 11C and a bent portion 11D. The straight portion 11C is a portion formed in a straight line shape, and is disposed over the entire section from one end portion 111A to the other end portion 111C of the reinforcement 111. The bent portion 11D is a portion disposed downward by folding back an end portion of the straight portion 11C, and has an end connected to the ECU 51 or the ECU 52. The bent portion 11D extends, for example, by obliquely folding back an end portion of the straight portion 11C and bending downward.

In the wire harness WHB according to the third embodiment, since the flexible substrate 11 is provided over the entire section of the trunk module 10, installation of the trunk side connector 12 attached to the flexible substrate 11 can be reduced. In the wire harness WHB according to the third embodiment, the flexible substrate 11 is provided over the entire section of the trunk module 10, so that the trunk module 10 can be formed thin. That is, since the trunk module 10 has a large number of transmission lines, when the trunk module is formed by bundling electric wires, the trunk module is formed to be large and thick. On the other hand, the wire harness WHB according to the third embodiment can be formed thinner than the case where the trunk module 10 is configured by bundling the electric wires.

As described above, in the wire harness WHB according to the third embodiment, since the flexible substrate 11 is provided over the entire section of the trunk module 10, the number of connection points of the connectors can be reduced.

Next, a wire harness according to a fourth embodiment will be described.

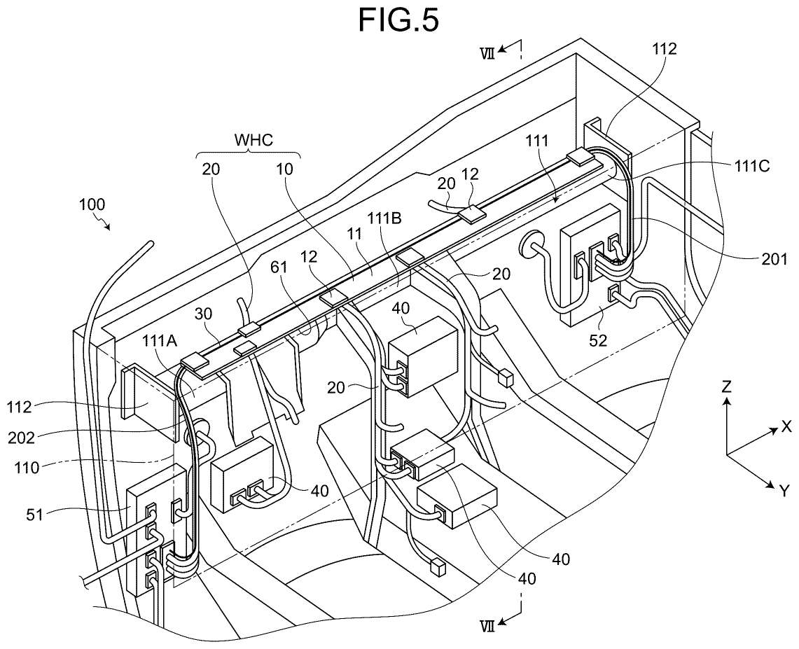

FIG. 5 is a perspective view of a wire harness WHC according to a fourth embodiment, and illustrates a state of being assembled to a vehicle 100. The wire harness WHC according to the fourth embodiment is configured substantially similarly to the wire harness WHA according to the second embodiment described above, and is different in including a first protective plate 61. That is, the wire harness WHC according to the fourth embodiment includes a first protective plate 61 that protects a flexible substrate 11 in a trunk module 10. The first protective plate 61 is a rectangular plate body extending long in one direction, and is formed of a material having higher rigidity than the flexible substrate 11. For example, the first protective plate 61 is made of resin. More specifically, the first protective plate 61 is made of a resin containing polyethylene as a main component, and is plastically deformed. That is, in the case where the first protective plate 61 is deformed according to an installation place, the deformed shape can be held.

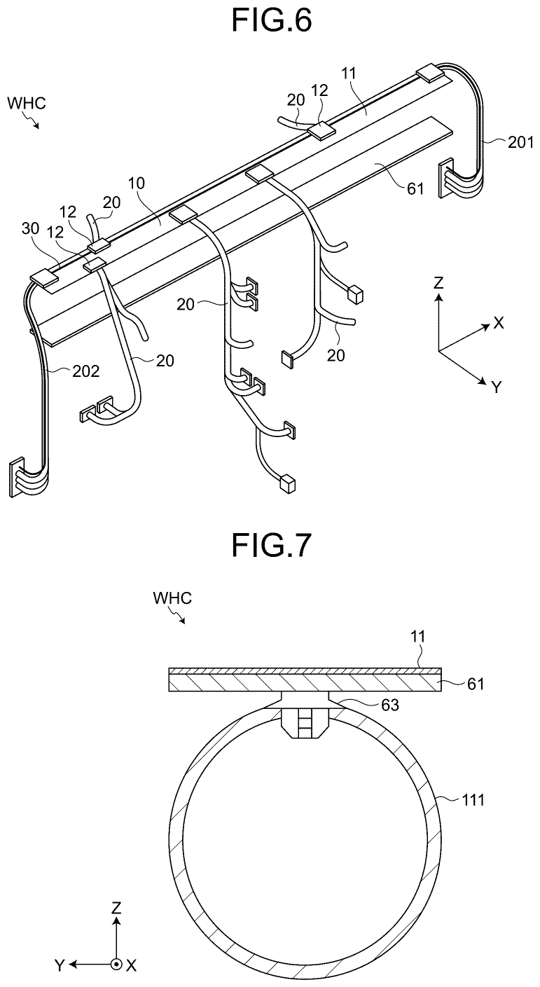

As illustrated in FIG. 6, the first protective plate 61 is formed to have the same size or substantially the same size as the flexible substrate 11, and is disposed on a reinforcement 111 side of the flexible substrate 11. For example, the flexible substrate 11 is stuck to the first protective plate 61 by using an adhesive or a double-sided tape. As illustrated in FIG. 7, the first protective plate 61 is attached to the reinforcement 111 using, for example, a clamp 63. The clamp 63 is inserted into the reinforcement 111 and fixed to the reinforcement 111. The clamp 63 is attached to the first protective plate 61 by adhesion, tape winding, or the like.

The flexible substrate 11 is disposed, for example, from a position of one end portion 111A of the reinforcement 111 to a position of the other end portion 111C. That is, the flexible substrate 11 is installed over the entire section of the reinforcement 111. Note that the flexible substrate 11 may be installed in a range of a partial section with respect to the reinforcement 111.

The wire harness WHC according to the fourth embodiment can protect the flexible substrate 11 by attaching the first protective plate 61 to the flexible substrate 11. In the wire harness WHC according to the fourth embodiment, since the flexible substrate 11 is attached to the reinforcement 111 through the first protective plate 61, an attached state of the flexible substrate 11 is stabilized. In the wire harness WHC according to the fourth embodiment, since the flexible substrate 11 has a plate shape, the first protective plate 61 can be formed in a simple shape with a plate shape, and the protector of the flexible substrate 11 can be provided at low cost. In the wire harness WHC according to the fourth embodiment, since the first protective plate 61 is made of resin, a shape of the first protective plate 61 can be easily bent and held, and the assemblability to the reinforcement 111 can be improved. In the wire harness WHC according to the fourth embodiment, since the flexible substrate 11 can be stably assembled by attaching the first protective plate 61 to the flexible substrate 11, the assembly to the vehicle can be easily automated.

As described above, the wire harness WHC according to the fourth embodiment includes the first protective plate 61 attached to the flexible substrate 11, so that the flexible substrate 11 can be physically protected and appropriately assembled to the reinforcement 111.

The wire harness WHC according to the fourth embodiment includes the clamp 63 fixed to the reinforcement 111, so that the flexible substrate 11 can be attached to the reinforcement 111 using the clamp 63.

Next, a wire harness according to a fifth embodiment will be described.

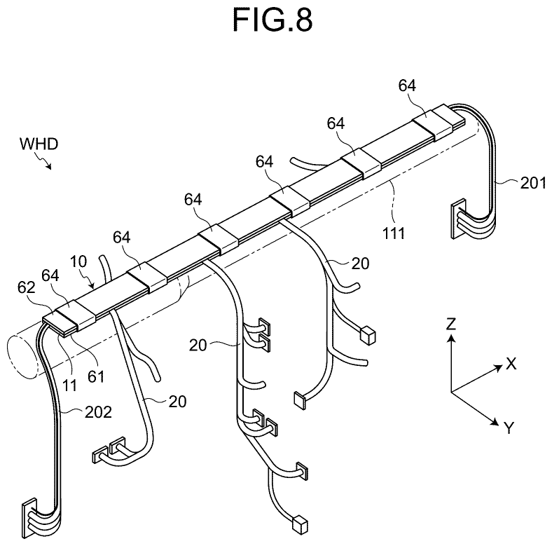

FIG. 8 is a perspective view of a wire harness WHD according to a fifth embodiment. A wire harness WHC according to the fourth embodiment is configured substantially similarly to the wire harness WHC according to the fourth embodiment described above, and is different in including a second protective plate 62. That is, the wire harness WHD according to the fifth embodiment includes a second protective plate 62 for protecting a flexible substrate 11 in a trunk module 10. The second protective plate 62 is a rectangular plate body extending long in one direction, and is made of a material having higher rigidity than the flexible substrate 11. For example, the second protective plate 62 is made of resin. More specifically, the second protective plate 62 is made of a resin containing polyethylene as a main component, and is plastically deformed. That is, in the case where the second protective plate 62 is deformed according to the installation place, the deformed shape can be held.

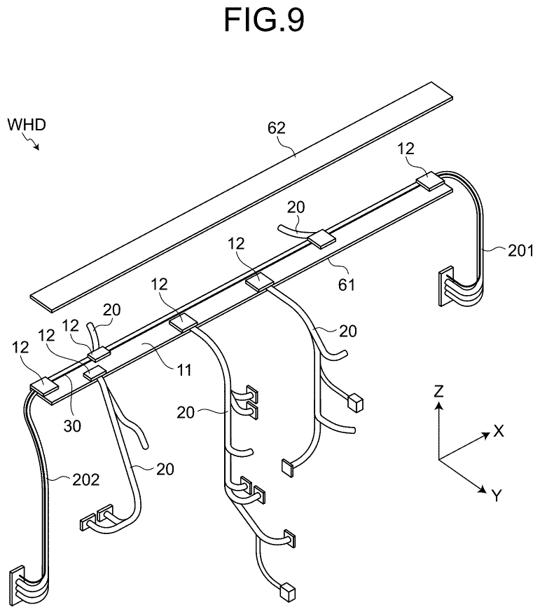

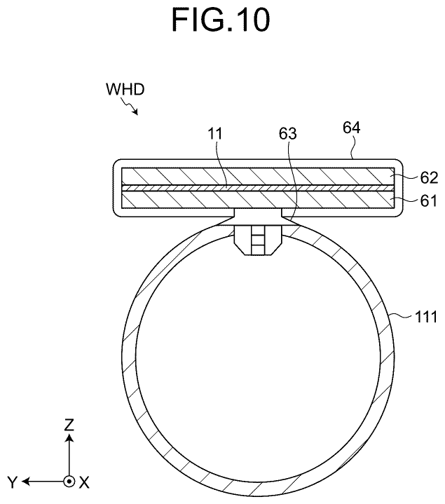

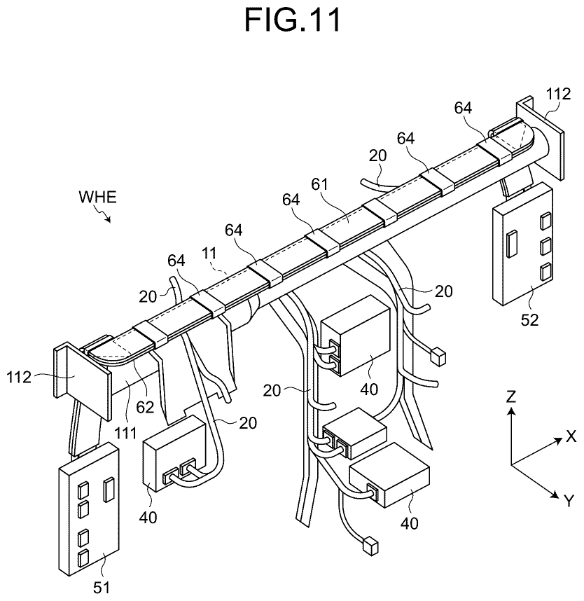

As illustrated in FIGS. 9 and 10, the second protective plate 62 is formed to have the same size or substantially the same size as the flexible substrate 11, and is disposed on the opposite side of the flexible substrate 11 from the reinforcement 111. That is, the second protective plate 62 sandwiches and protects the flexible substrate 11 together with the first protective plate 61. For example, the second protective plate 62 is attached to the flexible substrate 11 using an adhesive, a double-sided tape, or the like. A tape 64 is wound and attached around the first protective plate 61 and the second protective plate 62. The first protective plate 61, the second protective plate 62, and the flexible substrate 11 are integrated by the tape 64, and the first protective plate 61 and the second protective plate 62 are prevented from being detached from the flexible substrate 11.

The flexible substrate 11 is disposed, for example, from a position of one end portion 111A of the reinforcement 111 to a position of the other end portion 111C. That is, the flexible substrate 11 is installed over the entire section of the reinforcement 111. Note that the flexible substrate 11 may be installed in a range of a partial section with respect to the reinforcement 111.

The wire harness WHD according to the fifth embodiment can more accurately protect the flexible substrate 11 by including the second protective plate 62 that sandwiches and protects the flexible substrate 11 together with the first protective plate 61 in addition to the function and effect of the wire harness WHC according to the third embodiment. The wire harness WHD according to the fifth embodiment can prevent the first protective plate 61 and the second protective plate 62 from being detached from the flexible substrate 11 by winding and attaching the tape 64 around the first protective plate 61 and the second protective plate 62.

As described above, the wire harness WHD according to the fifth embodiment includes the second protective plate 62 that sandwiches and protects the flexible substrate 11 together with the first protective plate 61, whereby the flexible substrate 11 can be accurately protected.

Next, a wire harness according to a sixth embodiment will be described.

FIG. 11 is a perspective view of a wire harness WHE according to a sixth embodiment. The wire harness WHE according to the sixth embodiment is configured substantially similarly to the wire harness WHD according to the fifth embodiment described above, and is different in that a flexible substrate 11 is disposed over the entire section of a reinforcement 111 and the flexible substrate 11 is provided beyond the range of the reinforcement 111. In the wire harness WHE according to the sixth embodiment, a first protective plate 61 and a second protective plate 62 are also attached to a flexible substrate 11 provided beyond the range of the reinforcement 111 while sandwiching the flexible substrate 11 therebetween.

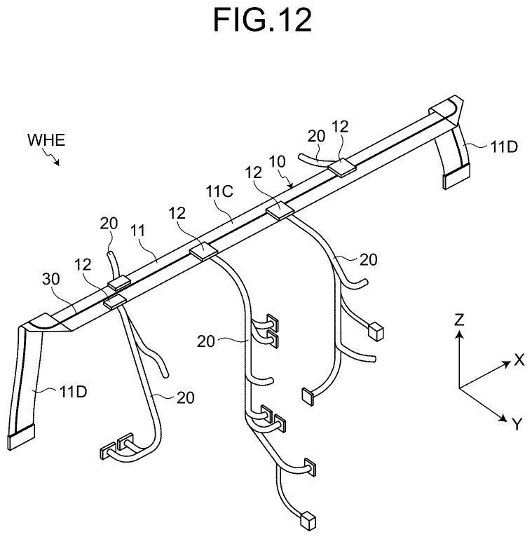

As illustrated in FIG. 12, the flexible substrate 11 of the wire harness WHE has a straight portion 11C and a bent portion 11D. The straight portion 11C is a portion formed in a straight line shape, and is disposed over the entire section from one end portion 111A to the other end portion 111C of the reinforcement 111. The bent portion 11D is a portion disposed downward by folding back an end portion of the straight portion 11C. The bent portion 11D extends, for example, by obliquely folding back an end portion of the straight portion 11C and bending downward.

In the wire harness WHE according to the sixth embodiment, since the flexible substrate 11 is provided over the entire section of the trunk module 10, the installation of the trunk side connector 12 attached to the flexible substrate 11 can be reduced. In the wire harness WHE according to the sixth embodiment, the flexible substrate 11 is provided over the entire section of the trunk module 10, so that the trunk module 10 can be formed thin.

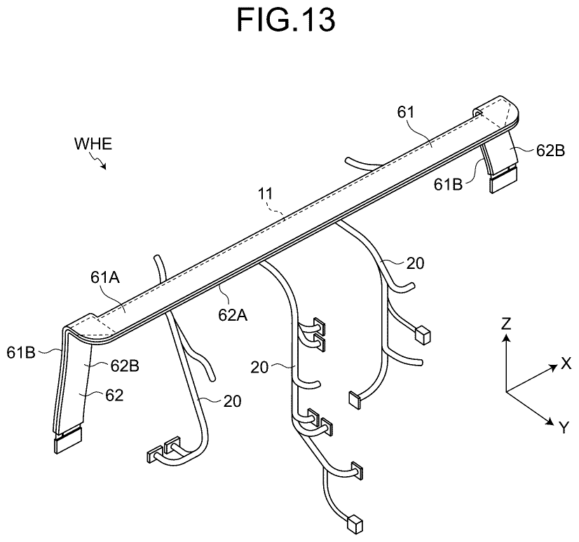

As illustrated in FIG. 13, the first protective plate 61 includes a straight portion 61A and a bent portion 61B along the flexible substrate 11 including a straight portion 11C and a bent portion 11D. The straight portion 61A is a portion formed in a straight line shape, and is disposed over the entire section from one end portion 111A to the other end portion 111C of the reinforcement 111. The bent portion 61B is provided at both ends of the straight portion 61A, and is a portion bent at each end and suspended downward.

The second protective plate 62 includes a straight portion 62A and a bent portion 62B along the flexible substrate 11 including the straight portion 11C and the bent portion 11D as in the first protective plate 61. The straight portion 62A is a portion formed in a straight line shape, and is disposed over the entire section from one end portion 111A to the other end portion 111C of the reinforcement 111. The bent portion 62B is provided at both ends of the straight portion 62A, and is a portion bent at each end and suspended downward.

The first protective plate 61 and the second protective plate 62 as described above can sandwich and protect the flexible substrate 11 having the straight portion 11C and the bent portion 11D.

As described above, the wire harness WHE according to the sixth embodiment can reliably protect the flexible substrate 11 by including the first protective plate 61 and the second protective plate 62 that sandwich and protect the flexible substrate 11 even when the flexible substrate 11 is bent and provided.

In the wire harness WHE according to the sixth embodiment, in the case where the flexible substrate 11 is bent and provided, the first protective plate 61 and the second protective plate 62 are bent corresponding to the bent shape of the flexible substrate 11 to sandwich and protect the flexible substrate 11. Therefore, the wire harness WHE according to the sixth embodiment can reliably protect the flexible substrate 11.

Although the embodiments of the present invention have been exemplified above, the above embodiments are merely examples, and are not intended to limit the scope of the invention. The above-described embodiments can be implemented in various other forms, and various omissions, substitutions, combinations, and changes can be made without departing from the gist of the invention. In addition, specifications (Structure, type, direction, form, size, length, width, thickness, height, number, arrangement, position, material, and the like) of each configuration, shape, and the like can be appropriately changed and implemented.

According to the wire harness of the present embodiment, the assemblability can be improved.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A wire harness, comprising:
a trunk module having a flexible substrate having flexibility; and
a branch wire module having an electric wire connected to the flexible substrate, wherein
the flexible substrate is disposed along a reinforcement provided in an instrument panel and extending in a vehicle width direction of a vehicle, and is assembled to the reinforcement.

2. The wire harness according to claim 1, wherein
the flexible substrate has one end extending to a position of one end portion of the reinforcement and the other end extending to between a central position of the reinforcement and a position of the other end portion, and
the wire harness further includes a first electric wire module connected to the other end of the flexible substrate and having an electric wire.

3. The wire harness according to claim 1, wherein
the flexible substrate extends from a position of one end portion of the reinforcement to a position of the other end portion of the reinforcement, and
the wire harness further includes
a first electric wire module connected to one end of the flexible substrate and having an electric wire; and
a second electric wire module connected to the other end of the flexible substrate and having an electric wire.

4. The wire harness according to claim 1, wherein
the trunk module is provided with the flexible substrate over an entire section, and
a first control unit is connected to one end of the flexible substrate, and a second control unit is connected to the other end of the flexible substrate.

5. The wire harness according to claim 4, wherein
the first control unit and the second control unit are disposed at positions deviated from each other in a direction intersecting an extending direction of the reinforcement, and
the flexible substrate is connected to the first control unit by bending one end side on the reinforcement, and is connected to the second control unit by bending the other end side on the reinforcement.

6. The wire harness according to claim 1, wherein
the trunk module includes a first protective plate attached to a side of the reinforcement of the flexible substrate.

7. The wire harness according to claim 6, further comprising:
a clamp attached to the first protective plate and fixed to the reinforcement.

8. The wire harness according to claim 6, wherein
the trunk module includes a second protective plate that is attached to the flexible substrate on a side opposite to the reinforcement and sandwiches and protects the first protective plate and the flexible substrate.

9. The wire harness according to claim 8, wherein
the trunk module is connected, at least at one end, to a control unit disposed at a position deviated in a direction intersecting with an extending direction of the reinforcement, and
the flexible substrate is connected to the control unit by bending the one end on the reinforcement, and
the first protective plate and the second protective plate are bent corresponding to a bent shape of the flexible substrate, and sandwich and protect the flexible substrate.
